(19) United States
(12) Patent Application Publication
(10) Pub. No.: US 2007/0093065 A1
(43) Pub. Date: Apr. 26, 2007

(54) Method for manufacturing a semiconductor wafer

(75) Inventor: Yoshirou Tsurugida, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/581,455

(22) Filed: Oct. 17, 2006

(30) Foreign Application Priority Data
Oct. 25, 2005 (JP) 2005-309977

(51) Int. Cl. H01L 21/461

(52) U.S. Cl. 438/692; 438/959

(57) ABSTRACT

A method is used for manufacturing a semiconductor wafer. The back surface of a semiconductor wafer is ground. The back surface is cleaned with ozone water. The back surface of the semiconductor wafer is etched with a mixed acid that contains hydrofluoric acid and nitric acid. The cleaning and etching are carried out alternately such that the cleaning and etching are each repeated a plurality of times. The etching is performed after the grinding, beginning when the semiconductor wafer is wet with the ozone water. The cleaning is performed after the etching, beginning when the semiconductor wafer is wet with an etching solution.

### BACKGROUND OF THE INVENTION

1. Field of the Invention

The present invention relates to a method for manufacturing a semiconductor wafer used for fabrication of a power device such as an insulated gate bipolar transistor (IGBT).

2. Description of the Related Art

A conventional IGBT is fabricated as follows: A semiconductor element is formed on a front surface of a semiconductor wafer, and then a photoresist film is applied to the front surface. Then, an acid-resistant tape is attached to the photoresist film followed by a removal film. A vacuum suction is applied to the removal film to hold the semiconductor wafer in place, and then the back surface of the semiconductor wafer is ground. After grinding of the back surface, the removal film is peeled off the semiconductor wafer for removing ground particles or debris. The side surface and back surface of the semiconductor wafer are washed to remove ground particles. Subsequently, the semiconductor wafer is immersed in a mixed acid of hydrofluoric acid (HF) or nitric acid (HNO₃) to etch the back surface, thereby grinding distortion resulting from grinding. Then, the semiconductor wafer is attached on a removal device by applying suction to the back surface of the wafer and then the acid-resistant tape is peeled off. The semiconductor wafer is then cleaned and subsequently a back surface electrode is formed on the back surface of the semiconductor wafer, thereby preventing the ground particles from adhering to the back surface.

The aforementioned conventional art suffers from a problem in that a large number of ground particles cannot be removed by washing the semiconductor wafer with, for example, pure water and remains on the back surface. Ground particles produced during a back grinding process may enter the back surface of the semiconductor wafer. Ground particles adhering to the back surface of the semiconductor wafer may be pushed into the back surface of the semiconductor wafer when the wafer is attached to a vacuum chuck by suction for transferring the semiconductor wafer to the next process after the back grinding process. If the ground particles are embedded into the back surface of the semiconductor wafer, the air bubbles are apt to adhere to the vicinity of the ground particles. The air bubbles become a barrier in an etching process in which the back surface is etched. Thus, the ground particles are difficult to remove by etching.

In addition, when the semiconductor wafer is attached to a vacuum chuck by vacuum suction prior to transfer of the wafer from the back grinding process to the next process, or when the semiconductor wafer is placed on a transfer belt, organic foreign materials may adhere to the wafer. The organic foreign material becomes a barrier or a “resist” in the etching process with the result that the marks of the chuck and belt remain on the back surface of the semiconductor wafer. For example, the inventor conducted an evaluation test as follows: When the back surface of the semiconductor wafer is etched to a depth of 30 μm in a mixed acid B of HF and HNO₃ (etching rate: 40 μm/min), 3030 ground particles of foreign material larger than 1.8 μm were observed on the semiconductor wafer, and the marks of the chuck and belt were observed.

The marks of chuck and belt and foreign matter such as grinding debris remaining on the back surface of the semiconductor wafer cause detachment of a diffusion layer during a subsequent ion implantation process and poor flatness of electrodes formed on the back surface of the semiconductor wafer. The detachment of a diffusion layer and poor flatness of electrodes result in a decrease in yield of the semiconductor elements fabricated on the semiconductor wafer.

### SUMMARY OF THE INVENTION

The present invention was made in view of the aforementioned problems.

An object of the invention is to provide a means for minimizing residues of foreign matter such as ground particles and the marks of a chuck and a belt resulting during an etching process performed after a back grinding process of a semiconductor wafer so that a clean back surface of a semiconductor wafer is obtained.

A method of manufacturing a semiconductor wafer includes the steps of:

a grinding a back surface of a semiconductor wafer;

cleaning the back surface of the semiconductor wafer with ozone water; and

etching the back surface of the semiconductor wafer with a mixed acid that contains hydrofluoric acid and nitric acid.

The cleaning and etching are carried out alternately such that the cleaning and etching are repeated a plurality of times.

The etching begins when the semiconductor wafer is wet with the ozone water and the cleaning begins when the semiconductor wafer is wet with an etching solution.

The back surface of the semiconductor wafer is etched to a depth of 30 μm or larger.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limiting the present invention, and wherein:

FIGS. 1 and 2 illustrate a method for manufacturing a semiconductor wafer according to the present invention;

FIG. 3 is a table that lists degrees of removal of foreign materials for different conditions; and

FIG. 4 illustrates the relation between a total depth of etching and the number of foreign material based on the evaluation in FIG. 3.

### DETAILED DESCRIPTION OF THE INVENTION

Embodiments of a method of manufacturing a semiconductor wafer according to the present invention will be described with reference to the drawings.

### Embodiment

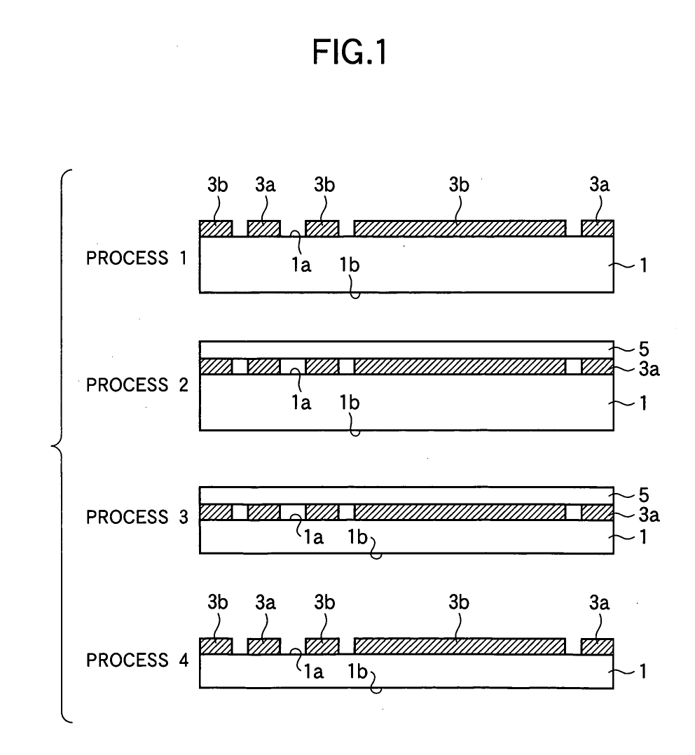

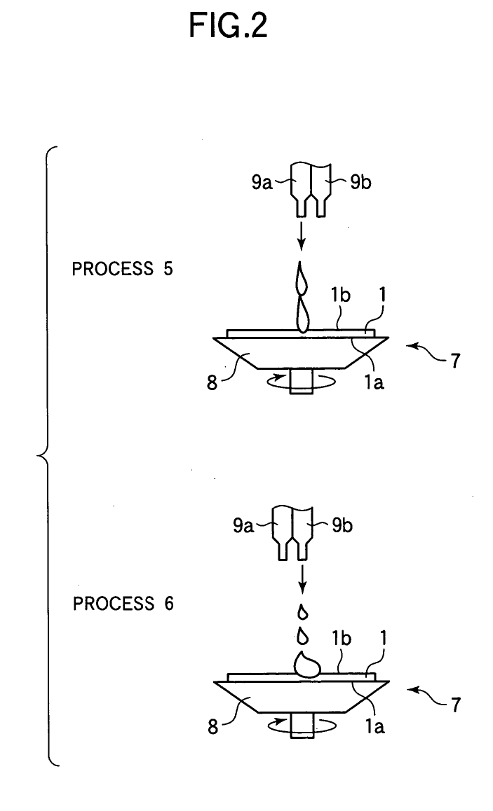

FIGS. 1 and 2 illustrate a method for manufacturing a semiconductor wafer according to the present invention. Referring to FIGS. 1 and 2, a semiconductor wafer 1 takes the form of a silicon substrate having a front surface la on which a plurality of semiconductor elements 3a (e.g., IGBTs) and surface electrodes 3b. The surface electrodes 3b serve as an anode electrode for the semiconductor elements. A protection tape 5 is a tape having an adhesive-coated side, and is used for use in a back grinding process. The protection tape 5 is attached to the semiconductor wafer 1 by placing the adhesive-coated side on the front surface 1a of the semiconductor wafer 1. The protection tape 5 protects the surface electrodes 3 formed on the front surface 1a of the semiconductor wafer 1 from damage, and prevents ground particles or debris from adhering to the surface electrode 3 during the back grinding process (later described “Process 3”).

Referring to FIG. 2, a spin-etching apparatus 7 includes an ozone water nozzle 9a that drips ozone water and an etching-solution nozzle 9b that drips a mixed acid D (etching rate is 10 μm/min) of hydrofluoric acid and nitric acid. The ozone water nozzle 9a and etching-solution nozzle 9b are positioned directly over the center of a turntable 8 of the spin-etching apparatus 7. The spin-etching apparatus 7 holds the semiconductor wafer 1 by vacuum suction from the front surface 1a of the semiconductor wafer 1. As the spin-etching apparatus 7 rotates, the etching solution and ozone water are dripped through the two nozzles 9a and 9b, respectively, onto the back surface 1b of the semiconductor wafer 1, and spread radially to etch the back surface 1b.

The method for manufacturing the semiconductor wafer 1 according to the present invention will be described with reference to FIGS. 1 and 2.

Process 1: The semiconductor wafer 1 is prepared. The semiconductor wafer 1 includes the surface electrodes 3 formed on the front surface 1a at predetermined locations for electrical connection of the plurality of semiconductor elements.

Process 2: The protection tape 5 is then stuck to the front surface 1a of the semiconductor wafer 1 by means of, for example, a pressure roller in the atmosphere. Then, the protection tape 5 is cut to the size of the semiconductor wafer 1, thereby covering the entire front surface 1a with the protection tape 5.

Process 3 (Wafer Back Grinding): The semiconductor wafer 1 is loosely inserted into a grinder through a fitting hole of the grinder such that the protection tape 5 contacts a bottom surface of the grinder. The grinder rotates on its axis while revolving about an axis. The bottom surface of the fitting hole is pressed against the protection tape 5, so that the back surface 1a of the semiconductor wafer 1 is ground by the grinder to a desired thickness (e.g., 180 μm).

During grinding, ground particles of silicon wafer tend to be lodged in the back surface 1b of the semiconductor wafer 1.

Process 4: A removal tape is stuck to the protection tape 5 and then the removal tape is removed together with the protection tape 5 from the front surface 1a of the semiconductor wafer 1. At this moment, the ground particles adhering to the protection tape 5 are removed together with the protection tape 5 from the semiconductor wafer 1.

After removing the protection tape 5 from the front surface 1b of the semiconductor wafer 1, the semiconductor wafer 1 is suction-mounted on a wafer mounting chuck with the back surface 1b abutting the wafer mounting chuck. Then, the semiconductor wafer 1 is transported by a transport belt to the spin-etching apparatus 7.

Process 5 (Ozone-Water Cleaning): The front surface 1a of the semiconductor wafer 1 is fixed on the turntable 8 of the spin-etching apparatus 7. Then, the turntable 8 is rotated, and the nozzle 9a drips the ozone water having a concentration of 20 ppm onto the center of the back surface 1b for, for example, 30 seconds, thereby causing the ozone water to radially spread by centrifugal force. In this manner, the back surface 1b of the semiconductor wafer 1 is washed.

During the washing of the back surface 1b, the ozone water causes oxidation of the back surface 1b to form an oxide (SiO₂) on the semiconductor wafer 1. The volume of the semiconductor wafer 1 increases due to oxidation. The increase in the volume of the semiconductor wafer 1 causes the lifting-off of the ground particles that have been embedded in the back surface 1b. The ozone water also oxidizes and/or decomposes organic foreign materials that would otherwise cause the marks of chuck and belt, and washes them away in the radial direction of the semiconductor wafer 1.

Process 6 (wet etching): After washing the semiconductor wafer 1 with ozone water, the supply of the ozone water is stopped, and then before the ozone water on the semiconductor wafer 1 dries up, the etching-solution nozzle 9b drips the mixed acid D (etching rate is 10 μm/min) of hydrofluoric acid and nitric acid onto the center of the back surface 1b of the semiconductor wafer 1 for a predetermined amount of time (e.g., 30 seconds), thereby causing the mixed acid D to spread by centrifugal force over the front surface 1a to etch the back surface 1b.

During oxidation of the back surface 1b, hydrofluoric acid removes the oxide formed on the back surface 1b together with the ground particles that have been embedded and lifted in the oxidized film. The oxide and ground particles are washed away from the mixed acid that spreads in the radial direction of the semiconductor wafer 1. After removal of the oxide, the back surface 1b is etched mainly by nitric acid to become smooth.

After etching the semiconductor wafer for the predetermined amount of time, the supply of the mixed acid D is stopped, and before the mixed acid D on the semiconductor wafer 1 dries up, the nozzle 9a drips the ozone water to clean the back surface 1b. The aforementioned Processes 5 and 6 a-re repeated a predetermined times, (e.g., 6 times) to remove parts of the back surface 1b damaged during grinding as well as ground particles.

In this manner, the back surface 1b of the semiconductor wafer 1 is etched to a predetermined total depth (e.g., 30 μm) , thereby obtaining the semiconductor wafer 1 having a designed thickness and a mirror-like back surface 1b. Subsequently, the semiconductor wafer 1 is washed with pure water or ozone water to remove the mixed acid D remaining on the back surface 1b. Then, a predetermined ion is implanted in the back surface 1b of the semiconductor 1, and then annealing is performed to activate the ion-implanted layer. Back surface electrodes as an anode electrode are then fabricated on the back surface 1b of the semiconductor wafer 1. Then, the semiconductor wafer 1 is diced with, for example, a dicing blade into individual pieces, thereby manufacturing semiconductor elements of the embodiment.

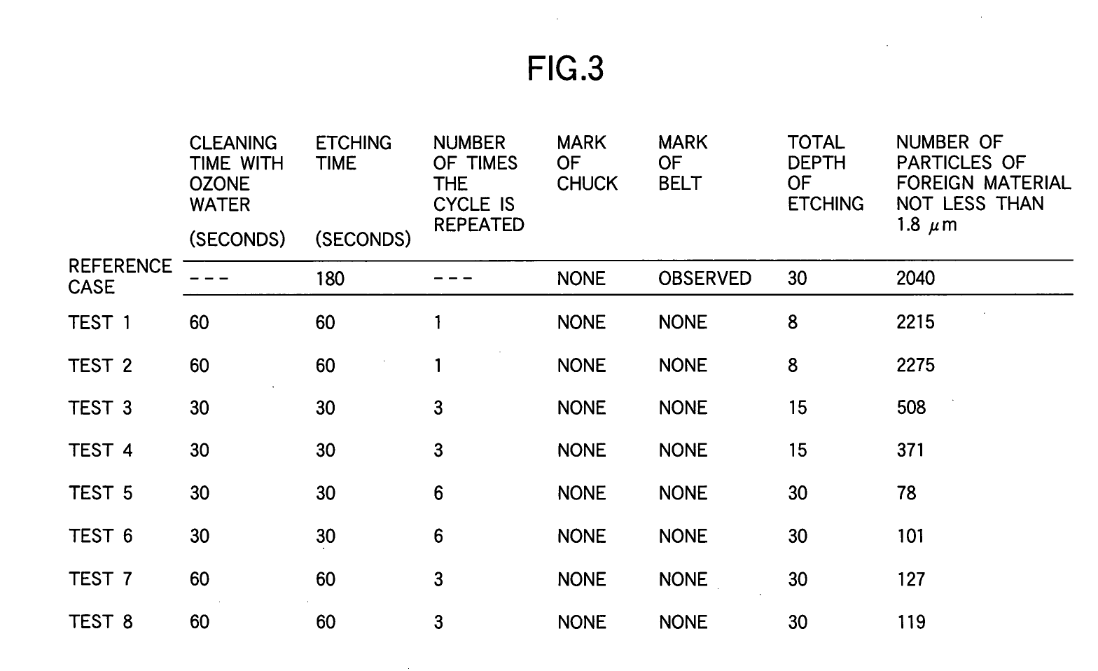

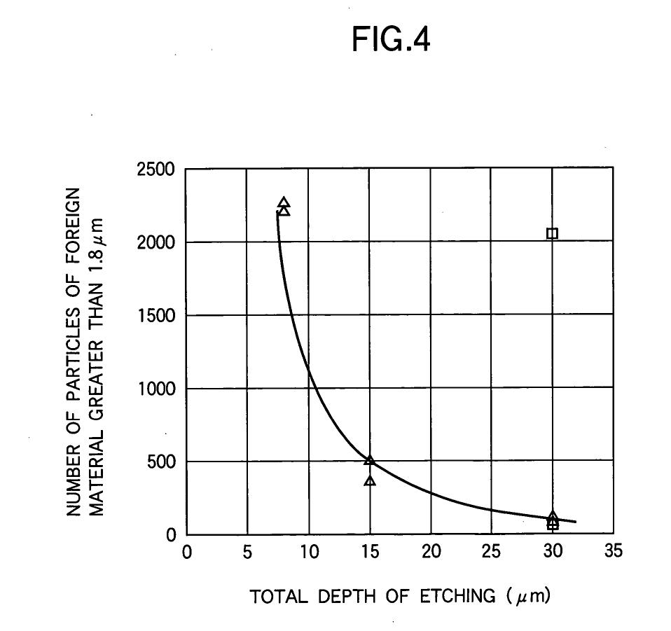

FIG. 3 is a table that lists degrees of removal of foreign materials such as ground particles and the marks of chuck and belt with respect to variables such as washing time, etching time, and the number of times that a cycle of washing process and etching process is repeated. FIG. 4 illustrates the relation between the total depth of etching and the number of particles of foreign material, the relation being derived from the evaluation in FIG. 3.

Referring to FIG. 3, when the etching process is performed for 180 seconds using a mixed acid D (reference case), the semiconductor wafer 1 is etched to a depth of 30 μm but the mark of belt remains.

When the ozone water cleaning (Process 5) is performed one time for 60 seconds and the etching (Process 6) is performed one time for 60 seconds for etching the semiconductor wafer 1 to a depth of 8 μm, the number of particles of foreign material remaining on the wafer 1 is substantially the same as in the reference case, but the mark of belt has disappeared (TEST 1 and TEST 2).

In other words, the combination of the ozone water cleaning process (Process 5) and the etching process (Process 6) shortens the total process time by about ⅓ of that for the reference case, resulting in the back surface 1b of the semiconductor wafer 1 of quality equal to or better than that of the reference case (TEST 1 and TEST 2). More over, when the combination of the ozone water cleaning process (Process 5) performed for 30 seconds with the etching process (Process 6) performed for 30 seconds is repeated 3 times (i.e., a total process time is 180 seconds), the semiconductor wafer 1 is etched to a depth of 15 μm, the number of ground particles being less than 25% of that of the reference case, and the mark of belt having disappeared (TEST 3).

In other words, the combination of the ozone water cleaning process (Process 5) with the etching process (Process 6) is capable of reducing the number of particles of foreign material to 75% or more of that of the reference case.

TEST 8 reveals that the number of particles of foreign material may be reduced by more than 94% of that of the reference case by performing the combination of the ozone water cleaning process with the etching process, provided that the combination is performed for twice as long a process time as for the reference case. The resulting back surface 1b is excellent in cleanliness. The aforementioned test results can be interpreted in terms of total depth of etching as follows: Referring to FIG. 4, if the semiconductor wafer 1 is etched to a depth of etching equal to or more than 15 μm, the number of particles of foreign material is reduced by 75% or more. If the semiconductor wafer 1 is etched to a depth of etching equal to or more than 30 μm, the number of particles of foreign material may be reduced by 94% or more regardless of the amount of etching time, the amount of time washing, and the number of times cycle of etching and washing processes are repeated.

In the embodiment, the back surface 1b of the semiconductor wafer 1 is preferably etched to a depth of 30 μm or more. The depth equal to 30 μm or more is effective in removing the damaged layer of the back surface 1b and ground particles remaining on the back surface 1b, so that the back surface 1b may be excellently clean.

In this manner, ground particles and the marks of chuck and belt may be removed from the back surface 1b of the semiconductor wafer 1 by performing the combination of the ozone water cleaning process and the etching process. Therefore, the ground particles remaining on the back surface 1b can be greatly reduced, preventing missing areas in a diffusion layer in the ion implantation process and poor flatness of the back surface electrode formed on the back surface as well as improving the yield of the semiconductor elements fabricated on the semiconductor wafer 1.

The ozone water cleaning process and the etching process are performed alternately in succession such that a following one of the two processes starts after a preceding one of the two processes when the semiconductor wafer 1 is still wet with the liquid used in the preceding process. This sequence of processes is advantageous in that ground particles and marks of chuck and belt do not adhere due to dry-up of the wafer 1, and thus shortens the overall process time for etching process and ozone water cleaning process. Oxide formed during the ozone water cleaning process is removed during the etching process. The etching process causes a fresh silicon surface to be exposed, so that a fresh oxide is formed efficiently on the silicon surface in the subsequent ozone water cleaning process and ground particles are lifted from the back surface 1b.

The number of ground particles remaining on the back surface 1b of the semiconductor wafer 1 is about 20% less when the combination of the ozone water cleaning process and the etching process is performed six times each process being performed for 30 seconds than when the combination of the ozone water cleaning process and the etching process are performed three times each process being performed for 60 seconds. In the embodiment, the etching process was performed using mixed acid D (HF and HNO₃, etching rate: 10 μm/min). Alternatively, the etching process may be performed using mixed acid B (proportions of HF and HNO₃ is different from mixed acid D, etching rate: 40 μm/min).

The invention being thus described, it will be obvious that the same may be varied in many ways. Such variations are not to be regarded as a departure from the spirit and scope of the invention, and all such modifications as would be obvious to one skilled in the art intended to be included within the scope of the following claims.

What is claimed is:

1. A method of manufacturing a semiconductor wafer comprising the steps of:
grinding a back surface of a semiconductor wafer;
cleaning the back surface of the semiconductor wafer with ozone water; and
etching the back surface of the semiconductor wafer with a mixed acid that contains hydrofluoric acid and nitric acid.

2. The method according to claim 1, wherein said cleaning and said etching are carried out alternately such that each of said cleaning and said etching is repeated a plurality of times.

3. The method according to claim 1, wherein said etching is performed after said cleaning, said etching beginning when the semiconductor wafer is wet with the ozone water.

4. The method according to claim 2, wherein said etching begins when the semiconductor wafer is wet with the ozone water, said cleaning beginning when the semiconductor wafer is wet with an etching solution.

5. The method according to claim 1, wherein the back surface of the semiconductor wafer is etched to a depth of 30 μm or larger.
